(19) United States
(12) Patent Application Publication
(10) Pub. No.: US 2026/0171181 A1
(43) Pub. Date: Jun. 18, 2026

(54) MEMORY DEVICE AND OPERATION METHOD THEREOF

(71) Applicant: Samsung Electronics Co., Ltd., Suwon-si (KR)

(72) Inventors: Yeungho OH, Suwon-si (KR); Yangjun HUH, Suwon-si (KR); Hyun-Sub YANG, Suwon-si (KR)

(73) Assignee: Samsung Electronics Co., Ltd., Suwon-si (KR)

(21) Appl. No.: 19/371,773

(22) Filed: Oct. 28, 2025

(30) Foreign Application Priority Data
Dec. 16, 2024 (KR) 10-2024-0187561

(51) Int. Cl. G11C 29/44; G11C 29/12; G11C 29/14

(52) U.S. Cl. CPC G11C 29/44; G11C 29/1201; G11C 29/14

(57) ABSTRACT

Disclosed is an operation method of a memory device which includes memory cells. The method includes receiving an injection mode signal from a memory controller, changing to one mode among injection modes based on the injection mode signal, receiving a first data signal including a command, an address, and an injection code from the memory controller, in the one mode, and performing an operation designated by the command on the memory cells designated by the address such that an error designated by the injection code is generated.

### CROSS-REFERENCE TO RELATED APPLICATIONS

This application claims priority under 35 U.S.C. § 119 to Korean Patent Application No. 10-2024-0187561 filed on Dec. 16, 2024, in the Korean Intellectual Property Office, the disclosures of which are incorporated by reference herein in their entireties.

### BACKGROUND

Example embodiments of the present disclosure described herein relate to semiconductor memories, and more particularly, relate to memory devices and operation methods thereof.

A semiconductor memory may be classified as a volatile memory, which may lose data stored therein when a power is turned off, such as a static random access memory (SRAM) or a dynamic random access memory (DRAM) or a nonvolatile memory, which may retain data stored therein even when a power is turned off, such as a flash memory, a phase-change RAM (PRAM), a magnetic RAM (MRAM), a resistive RAM (RRAM), or a ferroelectric RAM (FRAM).

The large capacity and high integration of the memory device may cause an error during an operation of the memory device, and many issues may occur in a post-processing operation for solving the error. A method of testing the post-processing operation of the memory device may include a method of modifying firmware or setting a fail bit in a memory controller. However, these methods may include limitations in that the methods fail or poorly attempt to accurately copy or simulate the error occurring during the actual operation of the memory device.

Accordingly, there is a desire for methods which may be capable of accurately copying or simulating an error occurring during the actual operation of the memory device and selectively generating an error up to the detailed structure of the memory device.

### SUMMARY

Embodiments of the present disclosure provide memory devices capable of accurately simulating an error occurring during actual operations of the memory devices and operation methods thereof.

According to some example embodiments, an operation method of a memory device which includes memory cells includes receiving an injection mode signal from a memory controller, changing to one mode among injection modes based on the injection mode signal, receiving a first data signal including a command, an address, and an injection code from the memory controller, in the one mode, and performing an operation designated by the command on the memory cells designated by the address such that an error designated by the injection code is generated.

According to some example embodiments, a storage device includes a memory controller that transmits a first data signal including a command, an address, and an injection code, memory cells, and a control circuit that performs an operation designated by the command on the memory cells designated by the address such that an error designated by the injection code is generated.

According to some example embodiments, a storage system includes a host that generates a control signal and an error test signal, a memory controller that generates a first data signal including a command, an address, and an injection code, based on the error test signal, and a memory device that performs an operation designated by the command on memory cells designated by the address such that an error designated by the injection code is generated.

According to some example embodiments, an operation method of a storage system comprising transmitting a control signal and an error test signal from a host, generating, by a memory controller, a normal mode signal from the control signa and an injection mode signal from the error test signal, generating a first data signal, generating, by the memory controller, a first data signal including a command, an address, and an injection code, based on the error test signal, transmit, by the memory controller, an injection mode signal to a memory device, based on the error test signal, and a normal mode signal to the memory device, based on the control signal, perform, by the memory device, an operation designated by the command on memory cells designated by the address such that an error designated by the injection code is generated.

In some example embodiments, the method may further include performing a repair operation on the error to determine a result of the repair operation.

### BRIEF DESCRIPTION OF THE FIGURES

The above and other objects and features of the present disclosure will become apparent by describing in detail embodiments thereof with reference to the accompanying drawings.

FIG. 1 is a diagram illustrating a storage device including a memory device according to some example embodiments of the present disclosure.

FIG. 2 is a diagram illustrating a method in which a memory device performs a test operation based on an injection code, according to some example embodiments of the present disclosure.

FIG. 3 is a diagram for describing planes, blocks, and pages included in a memory cell array of FIG. 1.

FIG. 4 is a diagram for describing a data signal, according to some example embodiments of the present disclosure.

FIG. 5 is a diagram for describing an injection code, according to some example embodiments of the present disclosure.

FIG. 6 is a diagram for describing the process of performing a command for generating an error through an injection code of FIG. 5.

FIG. 7 is a diagram for describing a threshold voltage distribution according to an erase count, according to some example embodiments of the present disclosure.

FIG. 8 is a diagram for describing an interface circuit, according to some example embodiments of the present disclosure.

FIG. 9 is a diagram for describing a method in which a memory device receives a mode signal, according to some example embodiments of the present disclosure.

FIG. 10 is a diagram for describing a method in which a memory device receives a data signal designating a program operation, according to some example embodiments of the present disclosure.

FIG. 11 is a diagram for describing a method in which a memory device receives a data signal designating an erase operation, according to some example embodiments of the present disclosure.

FIG. 12 is a diagram illustrating a storage system, according to some example embodiments of the present disclosure.

### DETAILED DESCRIPTION

Below, example embodiments of the present disclosure will be described in detail and clearly to such an extent that an ordinary one in the art easily carries out the present disclosure.

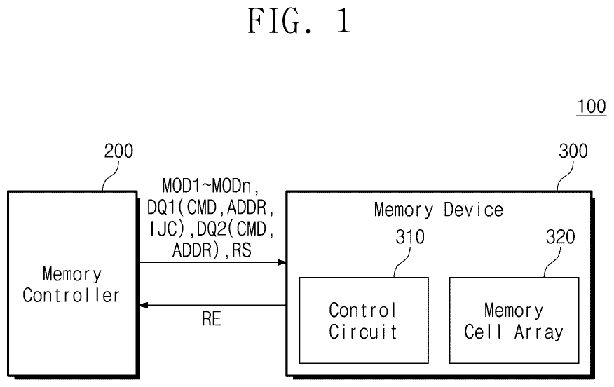

FIG. 1 is a diagram illustrating a storage device including a memory device according to some example embodiments of the present disclosure.

Referring to FIG. 1, a storage device 100 may include a memory controller 200 and a memory device 300. The memory device 300 may include a control circuit 310 and a memory cell array 320.

The memory controller 200 may be configured to overall control operations of the memory device 300. For example, the memory controller 200 may be configured to perform a program operation on the memory device 300 to store data. For example, the memory controller 200 may be configured to perform a read or erase operation on the memory device 300 such that the stored data are read or erased. The program, read, and erase operations of data may be initiated by an external host device or may be internally initiated by the memory controller 200.

The control circuit 310 may be configured to overall control operations of the memory cell array 320. For example, the memory cell array 320 may include a plurality of memory cells. For example, the control circuit 310 may be configured to read or erase data stored in the plurality of memory cells of the memory cell array 320. For example, the control circuit 310 may be configured to receive a data signal from the memory controller 200 and to perform the program, read, or erase operation on the plurality of memory cells based on the data signal.

The control circuit 310 may be configured to receive a second data signal DQ2 including a command CMD and an address ADDR from the memory controller 200. For example, the command CMD may designate the program, read, or erase operation. The control circuit 310 may be configured to control the memory cell array 320 depending on an operation designated by the command CMD. For example, the address ADDR may designate specific memory cells included in the memory cell array 320. The control circuit 310 may be configured to perform the program, read, or erase operation designated by the command CMD on the specific memory cells designated by the address ADDR. For example, when the command CMD designates the program operation, the control circuit 310 may be configured to receive a data signal including the command CMD, the address ADDR, and data from the memory controller 200. The control circuit 310 may be configured to program the data included in the data signal in the memory cells designated by the address ADDR.

In some example embodiments, the control circuit 310 may be configured to receive a first data signal DQ1 including the command CMD, the address ADDR, and an injection code IJC from the memory controller 200. For example, the injection code IJC may designate errors which occur during the operation of the memory device 300. For example, the operation may be an operation designated by the command CMD. For example, the injection code IJC may designate errors which occur during the execution of some operations included in the operation designated by the command CMD. For example, the errors may include the event that a fail or hang occurs during the program, read, or erase operation. For example, the errors may include the event that some memory cells do not reach a target threshold voltage during the incremental step pulse program (ISPP) operation in which selected memory cells are programmed multiple times while gradually increasing an application voltage of the program operation. For example, the program operation may include a cache program operation, and the cache program operation may mean a program operation in which the control circuit 310 transmits data to the memory cell array 320 through a cache (not illustrated) and simultaneously programs the data in the memory cell array 320. For example, the errors may include the event that some operations of the cache program operation are skipped or a fail occurs. For example, the errors may include the event that an operation of verifying a target threshold voltage of memory cells is skipped in the program operation or a fail occurs in the program operation. For example, the errors may occur in a minimum unit (or smallest unit) in which the control circuit 310 performs the program operation. For example, the errors may occur in units of word line of the memory cell array 320.

In some example embodiments, the control circuit 310 may be configured to generate the errors designated by the injection code IJC in the memory cell array 320. For example, the control circuit 310 may be configured to perform the operation designated by the command CMD on memory cells designated by the address ADDR such that an error designated by the injection code IJC is generated.

In some example embodiments, the control circuit 310 may be configured to receive a data signal based on a plurality of mode signals MOD1 to MODn. For example, the control circuit 310 may be configured to receive one of the plurality of mode signals MOD1 to MODn and to change to one of a plurality of modes. For example, the control circuit 310 may be configured to receive one of the plurality of mode signals MOD1 to MODn before receiving a data signal.

For example, when the normal mode signal MOD1 is received, the control circuit 310 may be configured to change to a first mode. In the first mode, the control circuit 310 may be configured to receive the second data signal DQ2 including the command CMD and the address ADDR.

For example, when one of a plurality of injection mode signals MOD2 to MODn is received, the control circuit 310 may be configured to change to one of the plurality injection mode signals MOD2 to MODn. For example, the control circuit 310 may receive the second mode signal MOD2 among the plurality of injection mode signals MOD2 to MODn and may change to a second mode. For example, the control circuit 310 may receive the third mode signal MOD3 among the injection mode signals MOD2 to MODn and may change to a third mode. In a plurality of injection modes, the control circuit 310 may be configured to receive the first data signal DQ1 including the command CMD, the address ADDR, and the injection code IJC. For example, the length of the first data signal DQ1 may be longer than the length of the second data signal DQ2.

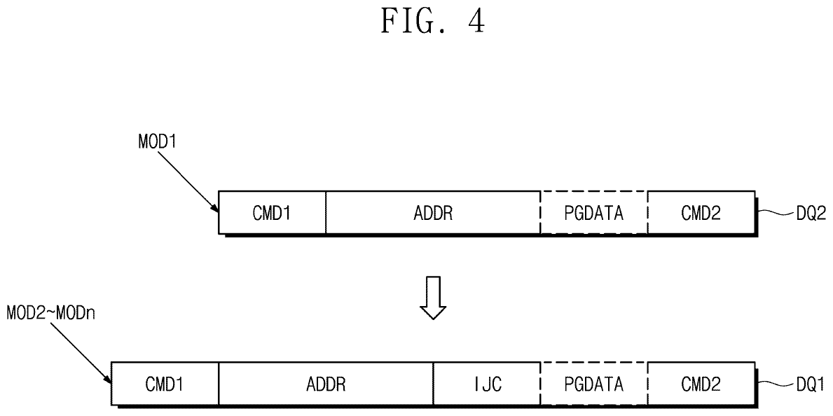

For example, the injection code IJC which the first data signal DQ1 includes may have different formats depending on the plurality of injection modes. For example, in the second mode, the injection code IJC may include an error address, an error stage, and/or an error type. For example, the error address may designate one or more memory cells of the memory cell array 320, the error stage may designate a first operation included in an operation designated by the command CMD, and the error type may designate a fail or a hang. For example, when the operation designated by the command CMD is the program operation, the first operation may be a verify operation or a voltage application operation. For example, in the third mode, the injection code IJC may include an erase count. The injection code IJC will be described in detail with reference to FIGS. 4 to 6.

In some example embodiments, the control circuit 310 may be configured to perform a repair operation on an error to determine a result RE of the repair operation. For example, when an error occurs during the operation of the control circuit 310, the memory controller 200 may be configured to perform the repair operation on the error. The memory controller 200 may be configured to transmit a repair signal RS to the control circuit 310, and the control circuit 310 may be configured to perform the repair operation based on the repair signal RS. For example, the repair operation may include an operation of again performing the program, read, or erase operation on memory cells in which an error occurs, a refresh operation using new memory cells, a soft program operation using a low-voltage pulse, an operation of recovering an error bit by using an error correction code (ECC), an operation of processing the corresponding memory cells as a bad block, and/or an operation of performing wear leveling. For example, the control circuit 310 may be configured to transmit the result RE of the repair operation to the memory controller 200. For example, the control circuit 310 may be configured to perform the read operation on the memory cells where the repair operation is performed and to determine the result RE of the repair operation. For example, the result RE of the repair operation may indicate whether the repair operation is completed and whether the repair operation is successful. In some example embodiments, the result RE may include a lifetime of the memory device.

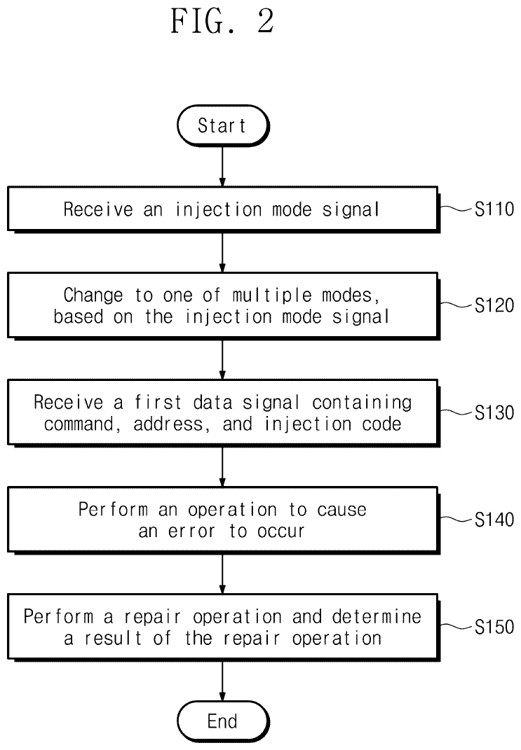

FIG. 2 is a diagram illustrating a method in which a memory device performs a test operation based on an injection code, according to some example embodiments of the present disclosure.

Referring to FIGS. 1 and 2, in operation S110, the memory device 300 may receive an injection mode signal from the memory controller 200. For example, the memory device 300 may receive the plurality of mode signals MOD1 to MODn from the memory controller 200, and the plurality of mode signals MOD1 to MODn may include the plurality of injection mode signals MOD2 to MODn. For example, the memory device 300 may receive one of the plurality of injection mode signals MOD2 to MODn from the memory controller 200.

In operation S120, the memory device 300 may change to one of a plurality of injection modes, based on the received injection mode signal. For example, the plurality of injection modes may be modes of simulating one or more of errors occurring during the operation of the memory device 300. For example, the memory device 300 may change to second to n-th modes, based on the injection mode signal.

In operation S130, the memory device 300 may receive the first data signal DQ1 including the command CMD, the address ADDR, and the injection code IJC. For example, the injection code IJC may designate errors based on the changed mode. For example, in the second mode, the injection code IJC may include an error address, an error stage, and an error type. For example, in the third mode, the injection code IJC may include an erase count.

In operation S140, the memory device 300 may perform an injection operation, based on the first data signal DQ1. For example, the injection operation may include an operation of generating an error during the operation of the memory device 300.

In some example embodiments, the memory device 300 may perform an operation designated by the command CMD on memory cells designated by the address ADDR such that an error designated by the injection code IJC is generated. For example, when the memory device 300 performs the operation designated by the command CMD, the injection code IJC may designate an error in which some operations are skipped, an error in which a fail or a hang occurs in some operations, an error according to a program/erase (P/E) cycle of specific memory cells, etc. For example, when the fail occurs, the memory device 300 may output a fail bit; when the hang occurs, the memory device 300 may not respond.

For example, the command CMD may designate the program operation. For example, the program operation may include a cache program operation, and the cache program operation may mean a program operation in which the control circuit 310 transmits data to the memory cell array 320 through a cache (not illustrated) and simultaneously programs the data in the memory cell array 320. For example, the address ADDR may designate first memory cells, and the injection code IJC may designate a fail of a first operation included in the program operation. In this case, the memory device 300 may perform the program operation such that a fail occurs in the first operation belonging to the program operation of the first memory cells.

For example, the command CMD may designate the erase operation, the address ADDR may designate second memory cells, and the injection code IJC may designate a hang of a second operation included in the program operation. In this case, the memory device 300 may perform the program operation such that a hang occurs in the second operation belonging to the erase operation of the second memory cells.

In some example embodiments, the command CMD may designate the program operation, the address ADDR may designate the second memory cells, and the injection code IJC may include an erase count. In this case, the memory device 300 may program the second memory cells to form an expected threshold voltage distribution which is based on the erase count. For example, the memory device 300 may store information about an expected threshold voltage distribution according to an erase count which a manufacturer provides. For example, the memory device 300 may calculate the expected threshold voltage distribution based on a degradation level of memory cells according to the erase count.

In operation S150, the memory device 300 may perform the repair operation on the error and may determine the result RE of the repair operation. For example, the memory controller 200 may transmit the repair signal RS to the memory device 300, and the memory device 300 may perform the repair operation based on the repair signal RS. For example, the memory device 300 may perform the read operation on the memory cells where the repair operation is performed and may determine the result RE of the repair operation. For example, the memory device 300 may transmit the result RE of the repair operation to the memory controller 200. In some example embodiments, the result RE may include if the error is repaired, and/or a lifetime of the memory device.

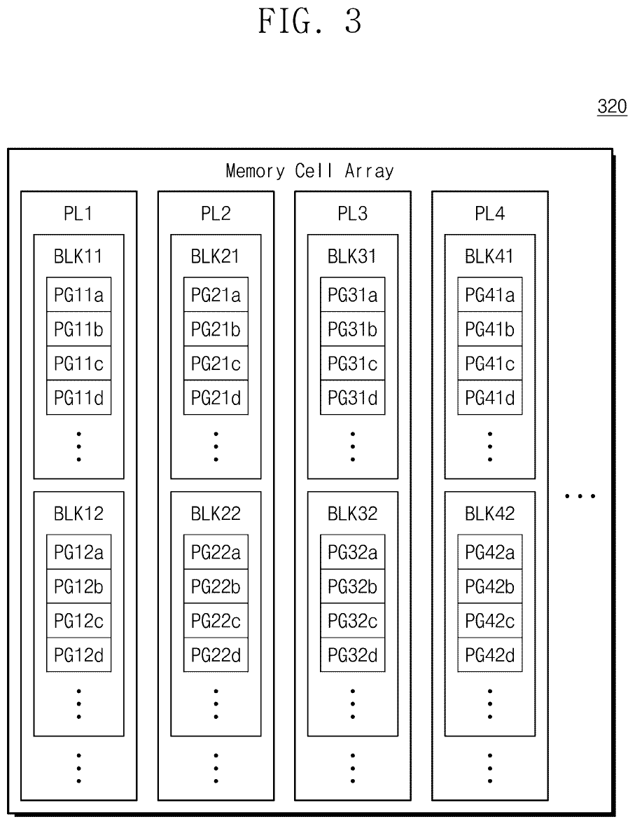

FIG. 3 is a diagram for describing planes, blocks, and pages included in a memory cell array of FIG. 1.

Referring to FIGS. 1 and 3, the memory cell array 320 may include a plurality of planes PL1 to PL4. The plane PL1 may include a plurality of blocks BLK11 and BLK12, the plane PL2 may include a plurality of blocks BLK21 and BLK22, the plane PL3 may include a plurality of blocks BLK31 and BLK32, and the plane PL4 may include a plurality of blocks BLK41 and BLK42. The block BLK11 may include pages PG11a, PG11b, PG11c and PG11d, and the block BLK12 may include pages PG12a, PG12b, PG12c and PG12d. The block BLK21 may include pages PG21a, PG21b, PG21c and PG21d, and the block BLK22 may include pages PG22a, PG22b, PG22c and PG22d. The block BLK31 may include pages PG31a, PG31b, PG31c and PG31d, and the block BLK32 may include pages PG32a, PG32b, PG32c and PG32d. The block BLK41 may include pages PG41a, PG41b, PG41c and PG41d, and the block BLK42 may include pages PG42a, PG42b, PG42c and PG42d.

In some example embodiments, the plurality of pages PG11a to PG11d, PG12a to PG12d, PG21a to PG21d, PG22a to PG22d, PG31a to PG31d, PG32a to PG32d, PG41a to PG41d, and PG42a to PG42d may include a plurality of memory cells targeted for the program or read operation of the memory device 300. The plurality pages PG11a to PG11d, PG12a to PG12d, PG21a to PG21d, PG22a to PG22d, PG31a to PG31d, PG32a to PG32d, PG41a to PG41d, and PG42a to PG42d may be a minimum unit (or smallest unit) in which the memory controller 200 performs the program or read operation on the memory cell array 320.

In some example embodiments, the memory controller 200 may be configured to program the plurality of planes PL1 to PL4 simultaneously in parallel. For example, the memory controller 200 may be configured to program four planes simultaneously in parallel. In this case, the memory controller 200 may be configured to perform the program operation in units of page of each of the plurality of planes PL1 to PL4.

For example, the address ADDR of the first data signal DQ1 may designate pages respectively located in the plurality of planes PL1 to PL4. For example, pages designated by the address ADDR may be included in four different planes PL1 to PL4. In this case, the control circuit 310 may perform an operation designated by the command CMD such that an error is generated in the first plane PL1 among the four planes PL1 to PL4. For example, the command CMD may designate the program operation, and the injection code IJC may designate the first plane PL1 and an error. The memory device 300 may perform the program operation such that an error is generated in the first plane PL1 among the four planes PL1 to PL4; in this case an error may not be generated in the remaining planes PL2 to PL4 other than the first plane PL1.

FIG. 4 is a diagram for describing a data signal, according to some example embodiments of the present disclosure.

Referring to FIGS. 1 and 4, the control circuit 310 may be configured to receive data signals of different formats based on a plurality of modes. For example, the control circuit 310 may be configured to receive one of the plurality of mode signals MOD1 to MODn and to change to one of the plurality of modes.

In some example embodiments, when the normal mode signal MOD1 is received, the control circuit 310 may be configured to change to the first mode. In the first mode, the control circuit 310 may be configured to receive the second data signal DQ2 including the command CMD and the address ADDR. That is, in the first mode, the memory controller 200 may be configured to transmit the second data signal DQ2 to the memory device 300. For example, before the control circuit 310 receives the plurality of injection mode signals MOD2 to MODn, the memory device 300 may be maintained in the first mode. For example, before the control circuit 310 receives the plurality of injection mode signals MOD2 to MODn, the format of a data signal which the memory device 300 receives may be the same as that of the second data signal DQ2.

According to some example embodiments, the command CMD may include a first command CMD1 and a second command CMD2. For example, when the command CMD designates the erase operation, the first command CMD1 may designate an erase preparation operation, and the second command CMD2 may designate an erase execution operation. For example, the control circuit 310 may sequentially receive the first command CMD1, the address ADDR, and the second command CMD2. For example, when the command CMD designates the program operation, the first command CMD1 may designate a program preparation operation, and the second command CMD2 may designate a program execution operation. In this case, program data PGDATA to be programmed may be further included in the second data signal DQ2. For example, the control circuit 310 may sequentially receive the first command CMD1, the address ADDR, the program data PGDATA, and the second command CMD2. As another example, the control circuit 310 may receive the program data PGDATA before the first command CMD1.

In some example embodiments, when one of a plurality of injection mode signals MOD2 to MODn is received, the control circuit 310 may be configured to change to one of the plurality of injection modes. In the plurality of injection modes, the control circuit 310 may be configured to receive the first data signal DQ1 including the command CMD, the address ADDR, and the injection code IJC. For example, the length of the first data signal DQ1 may be longer than the length of the second data signal DQ2.

For example, the command CMD of the first data signal DQ1 may include the first command CMD1 and the second command CMD2. For example, when the command CMD designates the erase operation, the first command CMD1 may designate the erase preparation operation, and the second command CMD2 may designate the erase execution operation. For example, the control circuit 310 may sequentially receive the first command CMD1, the address ADDR, the injection code IJC, and the second command CMD2. For example, when the command CMD designates the program operation, the first command CMD1 may designate the program preparation operation, and the second command CMD2 may designate the program execution operation. In this case, the program data PGDATA to be programmed may be further included in the first data signal DQ1. For example, the control circuit 310 may sequentially receive the first command CMD1, the address ADDR, the injection code IJC, the program data PGDATA, and the second command CMD2. That is, the injection code IJC may be received at a time point between the address ADDR and the program data PGDATA. As another example, the control circuit 310 may receive the program data PGDATA before the first command CMD1. In this case, the control circuit 310 may sequentially receive the first command CMD1, the address ADDR, the injection code IJC, and the second command CMD2.

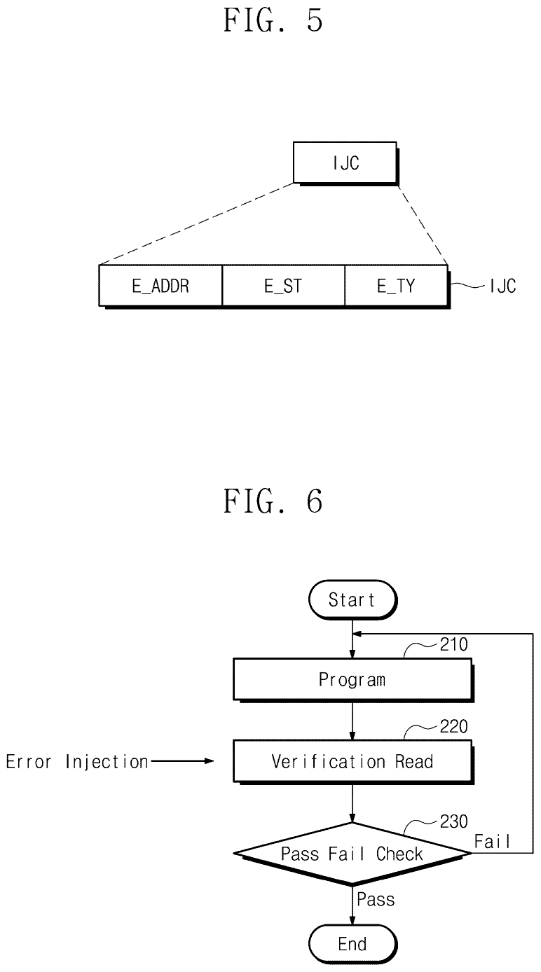

FIG. 5 is a diagram for describing an injection code, according to some example embodiments of the present disclosure.

Referring to FIGS. 1, 4, and 5, the injection code IJC may include an error address E_ADDR, an error stage E_ST, and/or an error type E_TY.

According to some example embodiments, the error address E_ADDR may designate one or more memory cells of the memory cell array 320, the error stage E_ST may designate a first operation included in an operation designated by the command CMD, and the error type E_TY may designate a fail or a hang. For example, the error address E_ADDR may include eight bits, the error stage E_ST may include eight bits, and the error type E_TY may include one bit. For example, when the operation designated by the command CMD is the program operation, the first operation may be a verify operation or a program inhibition operation. For example, when the operation designated by the command CMD is the erase operation, the first operation may be a voltage application operation, a verify operation, etc.

For example, the error address E_ADDR may designate memory cells where an error is to be generated. For example, the error address E_ADDR may indicate some or all of memory cells designated by the address ADDR. For example, the address ADDR may be configured to designate four different planes. For example, the address ADDR may designate pages of four different planes. For example, the error address E_ADDR may designate some or all of the four planes. For example, the error address E_ADDR may designate a first plane of the four planes. In this case, the memory device 300 may perform the program or erase operation such that an error is generated in the first plane, and the remaining planes other than the first plane may not generate an error. For example, the error address E_ADDR may designate a first plane and a second plane of the four planes. In this case, the memory device 300 may perform the program or erase operation such that an error is generated in the first plane and the second plane, and the remaining planes other than the first plane and the second plane may not generate an error. For example, the error address E_ADDR may designate a minimum unit (or smallest unit) in which the program or erase operation is performed. For example, the error address E_ADDR may designate a word line unit or a block unit, and the memory device 300 may perform the program or erase operation such that an error is generated in units of word line or block.

For example, the error stage E_ST may designate a first operation included in an operation designated by the command CMD for generating an error. For example, the error stage E_ST may designate some or all of operations belonging to the program or erase operation. For example, as the error stage E_ST designates the first operation, an error generated during the operation of the memory device 300 may be simulated. For example, in the program or erase operation, some programs may be skipped during the ISPP program operation. For example, in the program or erase operation, the verify operation may be failed or may be skipped. For example, in the cache program operation, an error may occur in some or all of the operations.

For example, the error type E_TY may designate a fail or a hang. For example, when the fail occurs, the memory device 300 may output a fail bit; when the hang occurs, the memory device 300 may not respond.

FIG. 6 is a diagram for describing the process of performing a command for generating an error through an injection code of FIG. 5.

Referring to FIGS. 1, 5, and 6, when the command CMD designates the program operation, an error may be generated in a first operation. That is, the injection code may include an error address designating one or more memory cells among the memory cells, an error stage designating a first operation included in the program operation, and an error type designating a fail or a hang. The control circuit 310 may perform the first operation on one or more memory cells such that the fail or the hang designated by the error type is generated.

According to some example embodiments, in operation S210, the control circuit 310 may perform the program operation on the memory cell array 320. For example, to generate a voltage for the program operation, the control circuit 310 may perform a pump operation to generate a high voltage. For example, the control circuit 310 may store the memory cells designated by the address ADDR as target memory cells in which the program operation is to be performed. For example, the control circuit 310 may apply an inhibit voltage to memory cell being not the target memory cells and may apply the program voltage to the target memory cells. The control circuit 310 may perform a step voltage application operation in which the program operation is performed while gradually increasing the program voltage. For example, the program voltage in operation S210 may be lower than the program voltage which is applied when the program operation is again performed after the fail is determined in operation S230.

In operation S220, the control circuit 310 may apply a verify voltage to the memory cell array 320. For example, the control circuit 310 may apply the verify voltage and may check whether the target memory cells are programmed. For example, the control circuit 310 may include information about a target threshold voltage distribution and may determine whether the target memory cells are included in the target threshold voltage distribution. For example, the control circuit 310 may store the target memory cells included in the target threshold voltage distribution as inhibit memory cells. For example, when the program operation is again performed after the fail is determined in operation S230, the control circuit 310 may apply an inhibit voltage to the inhibit memory cells. For example, the control circuit 310 may store the target memory cells not included in the target threshold voltage distribution as program memory cells. For example, when the program operation is again performed after the fail is determined in operation S230, the control circuit 310 may apply the program voltage to the program memory cells.

In operation S230, the control circuit 310 may perform a pass/fail check operation. For example, the control circuit 310 may determine whether all the target memory cells are included in the target threshold voltage distribution. For example, when all the target memory cells are included in the target threshold voltage distribution, the control circuit 310 may determine that the program operation is normally performed. For example, when the program operation is normally performed (Pass), the method may end. For example, when all the target memory cells are not included in the target threshold voltage distribution (Fail), the control circuit 310 may again perform operation S210.

According to some example embodiments, the error stage E_ST of the injection code IJC may designate some or all of operations belonging to the program operation. For example, the error stage E_ST may designate some or all of operation S210, operation S220, and operation S230. For example, the error stage E_ST may designate operations such as the pump operation, the inhibit voltage application operation, the step voltage application operation, the verify voltage application operation, and/or the pass/fail check operation. For example, the error stage E_ST may include a portion of an operation process of each of the above operations or the entire operation process thereof. Likewise, in the erase operation, the error stage E_ST may designate some or all of operations belonging to the erase operation.

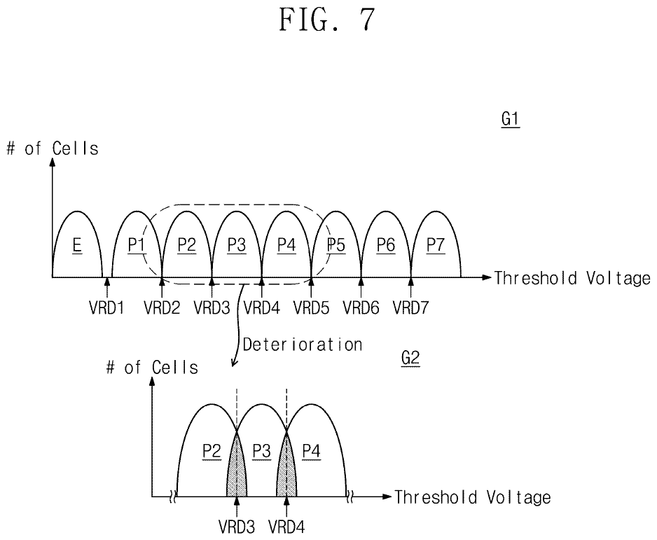

FIG. 7 is a diagram for describing a threshold voltage distribution according to an erase count, according to some example embodiments of the present disclosure.

A first graph G1 and a second graph G2 are illustrated in FIG. 7.

Referring to FIGS. 1, 4, and 7, the first graph G1 is a graph illustrating threshold voltage distributions of memory cells in the memory cell array 320, and the second graph G2 is a graph illustrating some of threshold voltage distributions when the memory cells deteriorates. A cell type of a memory cell and how an error occurs in a memory cell read operation will be described with reference to FIG. 7.

Referring to the first graph G1, the horizontal axis represents a threshold voltage, and the vertical axis represents the number of memory cells. The first graph G1 illustrates a threshold voltage distribution diagram of triple level cells (TLCs) each configured to store three bits. However, the scope of the present disclosure is not limited thereto. For example, each of the plurality of memory cells may be variously implemented with a single level cell (SLC), a multi-level cell (MLC), a quad-level cell (QLC), a penta level cell (PLC), etc., and embodiments of the present disclosure may be applied thereto.

For example, when the memory cell is programmed in an SLC manner, the memory cell may have one of an erase state “E” or a first program state P1. In this case, a voltage for distinguishing the states “E” and P1 may be greater than a first read voltage VR1 illustrated in FIG. 7. For another example, when the memory cell is programmed in an MLC manner, the memory cell may have the erase state “E” or one of the first to third program states P1 to P3. In this case, voltages VR1, VR2, and VR3 for distinguishing the states “E” and P1 to P3 may be greater than voltages illustrated in FIG. 7.

Referring to FIG. 7, the memory device 300 may store data in memory cells by controlling threshold voltages of the memory cells. For example, each of the memory cells may be programmed to have the erase state “E” or one of first to seventh program states P1 and P7.

The memory device 300 may read the data stored in the memory cells by sensing program states of the memory cells. For example, the memory device 300 may read the data stored in the memory cells by sensing the threshold voltages of the memory cells by using first to seventh read voltages VR1 to VR7. For example, the memory device 300 may perform the verify operation by using the first to seventh read voltages VR1 to VR7 as a verify voltage.

An example in which all the first to seventh read voltages VR1 to VR7 are positive voltages is illustrated in FIG. 7, but the scope of the present disclosure is not limited thereto. For example, the lowest voltage of the erase state “E” and the lowest voltage of the first program state P1 may be negative voltages. Below, for convenience of description, some example embodiments of the present disclosure will be described based on a triple level cell. However, the scope of the present disclosure is not limited thereto. For example, it should be understood that the present disclosure is applicable to various memory cells, which store two bits or four or more bits, such as an MLC, a QLC, and a PLC.

The second graph G2 illustrates the second to fourth program states P2 to P4 of the first graph G1 when the memory cells deteriorate. Referring to the second graph G2, some of program states of the memory cells may overlap each other. For example, referring to the third read voltage VR3, some of the memory cells may have the second program state P2, and the others thereof may have the third program state P3. For another example, referring to the fourth read voltage VR4, some of the memory cells may have the third program state P3, and the others thereof may have the fourth program state P4. The reason is that as the program and erase operations are repeated (e.g., as the number of program/erase (P/E) cycles increases), the performance of the memory cells deteriorate.

Referring to FIG. 7, in some example embodiments, the command CMD may designate the program operation, the address ADDR may designate the second memory cells, and the injection code IJC may include an erase count. In this case, the memory device 300 may program the second memory cells to form an expected threshold voltage distribution(s) which is based on the erase count. For example, the memory device 300 may store information about the expected threshold voltage distribution according to the erase count which a manufacturer provides. For example, the memory device 300 may calculate the expected threshold voltage distribution based on a degradation level of the memory cells according to the erase count. For example, the second graph G2 may be a graph illustrating the expected threshold voltage distribution.

For example, the memory device 300 may program the second memory cells to have the expected threshold voltage distribution of the second graph G2. In this case, the memory device 300 may fail to accurately determine the program states of the memory cells. In other words, an error may occur in the read operation. Referring to FIG. 1 together, the memory device 300 may perform the repair operation. The memory device 300 may detect the error and may correct the detected error. For example, the memory device 300 may include an ECC block, and the ECC block may perform error correction. For example, the memory device 300 may process a block including the second memory cells as a bad block and may perform wear leveling based on the expected threshold voltage distribution. For example, the memory device 300 may be configured to output a result of the repair operation. In some example embodiments, the results may include a lifetime of the memory device.

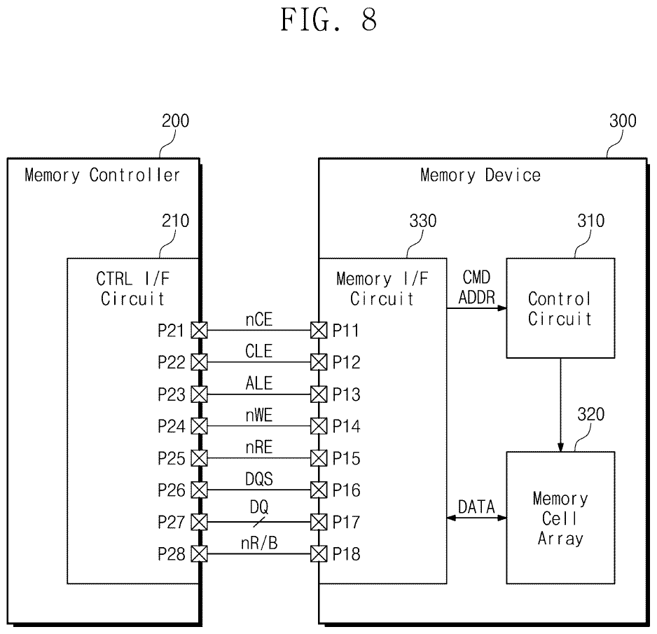

FIG. 8 is a diagram for describing an interface circuit, according to some example embodiments of the present disclosure.

Referring to FIG. 8, an interface circuit may include the memory controller 200 and the memory device 300. The memory device 300 may correspond to one of memory devices which communicate with the memory controller 200 based on one of a plurality of channels. The memory controller 200 may correspond to the memory controller 200 of FIG. 1.

The memory device 300 may include first to eighth pins P11 to P18, the control circuit 310, the memory cell array 320, and a memory interface circuit 330.

The memory interface circuit 330 may receive a chip enable signal nCE from the memory controller 200 through the first pin P11. The memory interface circuit 330 may transmit and receive signals to and from the memory controller 200 through the second to eighth pins P12 to P18 in response to the chip enable signal nCE. For example, when the chip enable signal nCE is in an enable state (e.g., at a low level), the memory interface circuit 330 may transmit and receive signals to and from the memory controller 200 through the second to eighth pins P12 to P18.

The memory interface circuit 330 may receive a command latch enable signal CLE, an address latch enable signal ALE, and a write enable signal nWE from the memory controller 200 through the second to fourth pins P12 to P14. Through the seventh pin P17, the memory interface circuit 330 may receive a data signal DQ from the memory controller 200 or may transmit the data signal DQ to the memory controller 200. The command CMD, the address ADDR, and data “DATA” may be transmitted through the data signal DQ.

The memory interface circuit 330 may receive a mode signal from the memory controller 200 through the seventh pin P17. For example, the mode signal may be a normal mode signal or one of a plurality of injection mode signals. For example, the format of the data signal DQ which is received through the seventh pin P17 may vary depending on the mode signal. For example, when the memory interface circuit 330 receive the normal mode signal, the memory device 300 may change to a first mode in which the memory device 300 operates depending on a second data signal, and the second data signal may include the command CMD and the address ADDR. Alternatively, the second data signal may include the command CMD, the address ADDR, and the data “DATA”. For example, when the memory interface circuit 330 receive the injection mode signal, the memory device 300 may change to a second mode in which the memory device 300 operates depending on a first data signal, and the first data signal may include the command CMD, the address ADDR, and an injection code. Alternatively, the first data signal may include the command CMD, the address ADDR, the data “DATA”, and the injection code.

For example, the data signal DQ may be transferred through a plurality of data signal lines. In this case, the seventh pin P17 may include a plurality of pins corresponding to the plurality of data signals DQ. For example, the command CMD of the data signal DQ may be received through a first pin among the plurality of pins of the seventh pin P17, and the address ADDR of the data signal DQ may be received through a second pin among the plurality of pins of the seventh pin P17.

The memory interface circuit 330 may obtain the command CMD from the data signal DQ which is received in an enable section (e.g., a high-level state) of the command latch enable signal CLE based on toggle timings of the write enable signal nWE. The memory interface circuit 330 may obtain the address ADDR from the data signal DQ which is received in an enable section (e.g., a high-level state) of the address latch enable signal ALE based on the toggle timings of the write enable signal nWE.

In an example embodiment, the write enable signal nWE may be maintained in a static state (e.g., at a high level or a low level) and may toggle between the high level and the low level. For example, the write enable signal nWE may toggle in a time period in which the command CMD or the address ADDR is transmitted. Thus, the memory interface circuit 330 may obtain the command CMD or the address ADDR based on toggle timings of the write enable signal nWE.

The memory interface circuit 330 may receive a read enable signal nRE from the memory controller 200 through the fifth pin P15. The memory interface circuit 330 may receive a data strobe signal DQS from the memory controller 200 through the sixth pin P16 or may transmit the data strobe signal DQS to the memory controller 200.

In a data (DATA) output operation of the memory device 300, the memory interface circuit 330 may receive the read enable signal nRE, which toggles through the fifth pin P15, before outputting the data “DATA”. The memory interface circuit 330 may generate the data strobe signal DQS toggling, based on the toggling of the read enable signal nRE. For example, the memory interface circuit 330 may generate the data strobe signal DQS that starts to toggle after a given delay (e.g., tDQSRE) from a time at which the read enable signal nRE starts to toggle. The memory interface circuit 330 may transmit the data signals DQ including the data “DATA” based on toggle timings of the data strobe signal DQS. Accordingly, the data “DATA” may be transmitted to the memory controller 200 in a state of being aligned with the toggle timings of the data strobe signal DQS.

In a data (DATA) program operation of the memory device 300, when the data signal DQ including the data “DATA” is received from the memory controller 200, the memory interface circuit 330 may receive the data strobe signal DQS, which toggles, from the memory controller 200 together with the data “DATA”. The memory interface circuit 330 may obtain the data “DATA” from the data signal DQ based on toggle timings of the data strobe signal DQS. For example, the memory interface circuit 330 may sample the data signal DQ at rising and falling edges of the data strobe signal DQS and may obtain the data “DATA”.

The memory interface circuit 330 may transmit a ready/busy output signal nR/B to the memory controller 200 through the eighth pin P18. The memory interface circuit 330 may transmit status information of the memory device 300 to the memory controller 200 through the ready/busy output signal nR/B. When the memory device 300 is in a busy state (e.g., when internal operations of the memory device 120 are being performed), the memory interface circuit 330 may transmit the ready/busy output signal nR/B indicating the busy state to the memory controller 200. When the memory device 300 is in a ready state (e.g., when the internal operations of the memory device 300 are not performed or are completed), the memory interface circuit 330 may transmit the ready/busy output signal nR/B indicating the ready state to the memory controller 200. For example, while the memory device 300 reads the data “DATA” from the memory cell array 320 in response to a page read command, the memory interface circuit 330 may transmit the ready/busy output signal nR/B indicating the busy state (e.g., having the low level) to the memory controller 200. For example, while the memory device 300 programs the data “DATA” in the memory cell array 320 in response to a program command, the memory interface circuit 330 may transmit the ready/busy output signal nR/B indicating the busy state to the memory controller 200.

The control circuit 310 may overall control various kinds of operations of the memory device 300. The control circuit 310 may receive the command/address CMD/ADDR obtained from the memory interface circuit 330. The control circuit 310 may generate control signals for controlling other components of the memory device 300 in response to the received command/address CMD/ADDR. For example, the control circuit 310 may generate various kinds of control signals for programming or erasing the data “DATA” in the memory cell array 320 or reading the data “DATA” from the memory cell array 320.

The memory cell array 320 may store the data “DATA” obtained from the memory interface circuit 330 under control of the control circuit 310. The memory cell array 320 may output the stored data “DATA” to the memory interface circuit 330 under control of the control circuit 310.

The memory cell array 320 may include a plurality of memory cells. For example, the plurality of memory cells may be flash memory cells. However, the present disclosure is not limited thereto, and the memory cells may be RRAM (Resistive Random Access Memory) cells, FRAM (Ferroelectric Random Access Memory) cells, PRAM (Phase Change Random Access Memory) cells, TRAM (Thyristor Random Access Memory) cells, MRAM (Magnetic Random Access Memory) cells or the like. Some example embodiments of the present disclosure will be described based on some example embodiments where memory cells are NAND flash memory cells.

The memory controller 200 may include first to eighth pins P21 to P28 and a controller interface circuit 410. The first to eighth pins P21 to P28 may respectively correspond to the first to eighth pins P11 to P18 of the memory device 300.

The controller interface circuit 410 may transmit a chip enable signal nCE to the memory device 300 through the first pin P21. The controller interface circuit 410 may transmit and receive signals to and from the memory device 300, which is selected by the chip enable signal nCE, through the second to eighth pins P22 to P28.

The controller interface circuit 410 may transmit the command latch enable signal CLE, the address latch enable signal ALE, and the write enable signal nWE to the memory device 300 through the second to fourth pins P22 to P24. The controller interface circuit 410 may transmit or receive the data signal DQ to and from the memory device 300 through the seventh pin P27.

The controller interface circuit 410 may transmit the data signal DQ including the command CMD or the address ADDR to the memory device 300 together with the write enable signal nWE, which toggles. The controller interface circuit 410 may transmit the data signal DQ including the command CMD to the memory device 300 by transmitting the command latch enable signal CLE having an enable state and may transmit the data signal DQ including the address ADDR to the memory device 300 by transmitting the address latch enable signal ALE having an enable state.

The controller interface circuit 410 may transmit the read enable signal nRE to the memory device 300 through the fifth pin P25. The controller interface circuit 410 may receive or transmit the data strobe signal DQS from or to the memory device 300 through the sixth pin P26.

In a data (DATA) output operation of the memory device 300, the controller interface circuit 410 may generate the read enable signal nRE which toggles and may transmit the read enable signal nRE to the memory device 300. For example, before outputting the data “DATA”, the controller interface circuit 410 may generate the read enable signal nRE which is changed from a static state (e.g., a high level or a low level) to a toggling state. Accordingly, the memory device 300 may generate the data strobe signal DQS, which toggles, based on the read enable signal nRE. The controller interface circuit 410 may receive the data signal DQ including the data “DATA” together with the data strobe signal DQS, which toggles, from the memory device 300. The controller interface circuit 410 may obtain the data “DATA” from the data signal DQ based on a toggle timing of the data strobe signal DQS.

In a data (DATA) input operation of the memory device 300, the controller interface circuit 410 may generate the data strobe signal DQS which toggles. For example, before transmitting the data “DATA”, the controller interface circuit 410 may generate the data strobe signal DQS which is changed from a static state (e.g., a high level or a low level) to a toggling state. The controller interface circuit 410 may transmit the data signal DQ including the data “DATA” to the memory device 300 based on toggle timings of the data strobe signal DQS.

The controller interface circuit 410 may receive the ready/busy output signal nR/B from the memory device 300 through the eighth pin P28. The controller interface circuit 410 may determine the state of the memory device 300 based on the ready/busy output signal nR/B.

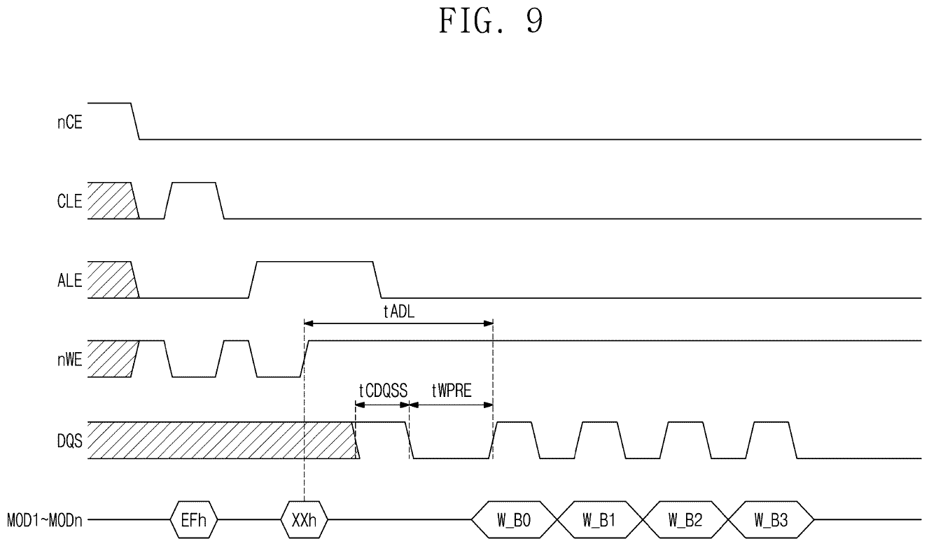

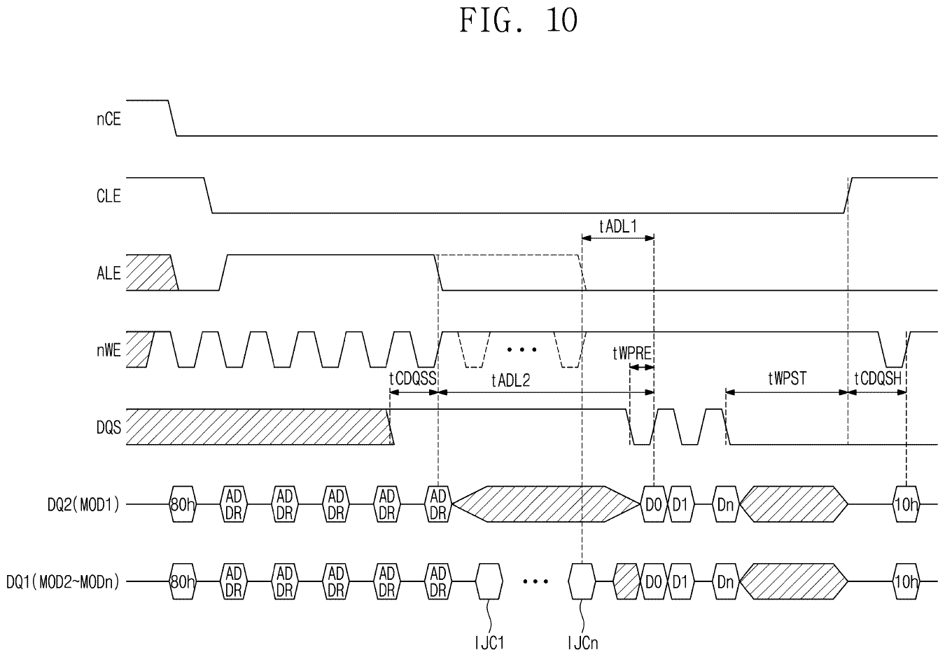

FIG. 9 is a diagram for describing a method in which a memory device receives a mode signal, according to some example embodiments of the present disclosure.

Referring to FIGS. 1, 8, and 9, the chip enable signal nCE, the command latch enable signal CLE, the address latch enable signal ALE, the write enable signal nWE, the data strobe signal DQS, and the plurality of mode signals MOD1 to MODn are illustrated. The signals nCE, CLE, ALE, nWE, DQS, and DQ may have the states or levels described with reference to FIG. 8, and the plurality of mode signals MOD1 to MODn described with reference to FIG. 1 may be transmitted through the data signal DQ. Regardless of whether the corresponding signal is at the high level or low level in hatched regions of FIG. 9, the memory device 300 may receive a mode signal.

According to some example embodiments, the plurality of mode signals MOD1 to MODn may include a command code EFh, an address code XXh, and a data code W_B0 to W_B3. For example, the command code EFh may include a command for enabling a specific function of the memory device 300 or changing a setting value. For example, the address code XXh may include information about the function to be enabled or the setting value. For example, the data code W_B0 to W_B3 may include detailed parameters for the specific function. For example, through the command code EFh, the address code XXh, and the data code W_B0 to W_B3, the memory device 300 may change to one mode among the plurality of injection modes. For example, the memory device 300 may change to one mode among the plurality of injection modes based on the address code XXh newly defined, and the data code W_B0 to W_B3. For example, based on the data code W_B0 to W_B3, the memory device 300 may change to a second mode to an n-th mode.

For example, as the chip enable signal nCE toggles to the enable state (e.g., the low level), the memory interface circuit 330 may transmit/receive the signals CLE, ALE, nWE, DQS, and MOD1 to MODn to/from the memory controller 200. For example, while the signals CLE, ALE, nWE, DQS, and MOD1 to MODn are received, the chip enable signal nCE may maintain the low level.

For example, the memory interface circuit 330 may receive the command CMD in the enable time period (e.g., at the high level) of the command latch enable signal CLE and may receive the address ADDR in the enable time period (e.g., at the high level) of the address latch enable signal ALE. For example, the command CMD and the address ADDR may be received based on the toggle timings of the write enable signal nWE.

For example, the memory interface circuit 330 may receive the command code EFh through the plurality of mode signals MOD1 to MODn based on toggle timings of the write enable signal nWE. For example, when the chip enable signal nCE is at the low level, the command latch enable signal CLE is at the high level, and the address latch enable signal ALE is at the low level, the memory interface circuit 330 may receive the command code EFh. For example, when the write enable signal nWE toggles from the low level to the high level, the command code EFh may be received.

For example, the memory interface circuit 330 may receive the address code XXh through the plurality of mode signals MOD1 to MODn based on toggle timings of the write enable signal nWE. For example, when the chip enable signal nCE is at the low level, the address latch enable signal ALE is at the high level, the command latch enable signal CLE is at the low level, the memory interface circuit 330 may receive the address code XXh. For example, when the write enable signal nWE toggles from the low level to the high level, the address code XXh may be received.

For example, the memory interface circuit 330 may receive the data strobe signal DQS which starts to toggle after the address code XXh is received and a preparation time tADL passes. The memory interface circuit 330 may receive the data code W_B0 to W_B3 based on toggle timings of the data strobe signal DQS.

For example, the data strobe signal DQS may toggle after a time tCDQSS for setting up the data strobe signal DQS and a time tWPRE for aligning signals to receive the data code W_B0 to W_B3.

For example, the memory interface circuit 330 may receive the data code W_B0 to W_B3 through the plurality of mode signals MOD1 to MODn based on toggle timings of the data strobe signal DQS. For example, when the chip enable signal nCE is at the low level, the address latch enable signal ALE is at the low level, and the command latch enable signal CLE is at the high level, the memory interface circuit 330 may receive the data code W_B0 to W_B3. For example, when the data strobe signal DQS toggles from the low level to the high level, the data code W_B0 to W_B3 may be received.

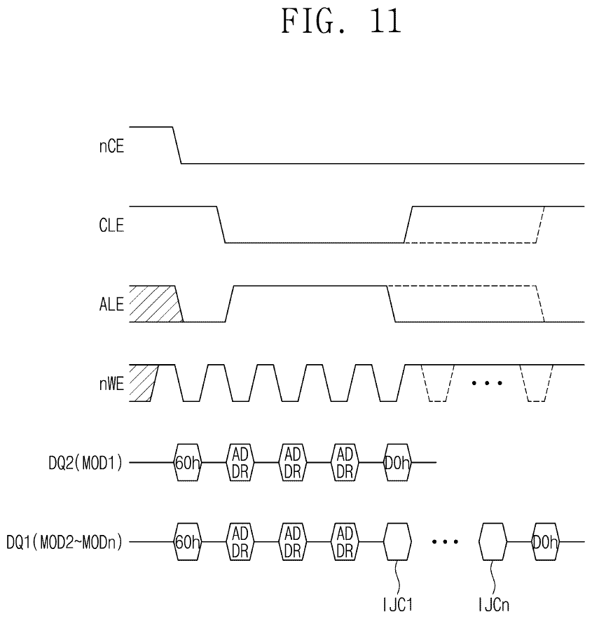

FIG. 10 is a diagram for describing a method in which a memory device receives a data signal designating a program operation, according to some example embodiments of the present disclosure.

Referring to FIGS. 1, 8, and 10, the chip enable signal nCE, the command latch enable signal CLE, the address latch enable signal ALE, the write enable signal nWE, the data strobe signal DQS, the first data signal DQ1, and the second data signal DQ2 are illustrated. The signals nCE, CLE, ALE, nWE, and DQS may have the states or levels described with reference to FIG. 8, and the data signals DQ1 and DQ2 described with reference to FIG. 1 may be transmitted. Regardless of whether the corresponding signal is at the high level or low level in hatched regions of FIG. 10, the memory device 300 may receive the data signals DQ1 and DQ2.

According to some example embodiments, as described above, the memory device 300 may receive the normal mode signal MOD1; in the first mode, the memory device 300 may receive the second data signal DQ2 including the command CMD, the address ADDR, and data. The memory device 300 may receive the plurality of injection mode signals MOD2 to MODn; in the second mode to the n-th mode, the memory device 300 may receive the first data signal DQ1 including the command CMD, the address ADDR, data, and the injection code IJC.

For example, the second data signal DQ2 may include command codes 80h and 10h, the address code ADDR, and a data code D0 to Dn, and the first data signal DQ1 may include the command codes 80h and 10h, the address code ADDR, the data code D0 to Dn, and an injection code IJC1 to IJCn. For example, referring to the first data signal, the address code ADDR, the injection code IJC1 to IJCn, and the data code D0 to Dn may be sequentially received.

For example, as the chip enable signal nCE toggles to the enable state (e.g., the low level), the memory interface circuit 330 may transmit/receive the signals CLE, ALE, nWE, DQS, DQ1, and DQ2 to/from the memory controller 200. For example, while the signals CLE, ALE, nWE, DQS, DQ1, and DQ2 are received, the chip enable signal nCE may maintain the low level.

For example, the memory interface circuit 330 may receive the command codes 80h and 10h of the first data signal DQ1 or the second data signal DQ2, based on toggle timings of the write enable signal nWE. For example, the command codes 80h and 10h may designate the program operation. For example, when the chip enable signal nCE is at the low level, the command latch enable signal CLE is at the high level, and the address latch enable signal ALE is at the low level, the memory interface circuit 330 may receive the command codes 80h and 10h. For example, when the write enable signal nWE toggles from the low level to the high level, the command codes 80h and 10h may be received. For example, the memory interface circuit 330 may receive the command code 10h after a given time tWPST and tCDQSH from a time point at which the data code D0 to Dn is completely received.

For example, the memory interface circuit 330 may receive the address code ADDR of the first data signal DQ1 or the second data signal DQ2, based on toggle timings of the write enable signal nWE. For example, when the chip enable signal nCE is at the low level, the address latch enable signal ALE is at the high level, and the command latch enable signal CLE is at the low level, the memory interface circuit 330 may receive the address code ADDR. For example, when the write enable signal nWE toggles from the low level to the high level, the address code ADDR may be received.

For example, the memory interface circuit 330 may receive the injection code IJC1 to IJCn of the first data signal DQ1, based on toggle timings of the write enable signal nWE. For example, as described with reference to FIGS. 4 to 7, the injection code IJC1 to IJCn may include the error address, the error stage, and the error type or may include the erase count. For example, when the chip enable signal nCE is at the low level, the address latch enable signal ALE is at the high level, and the command latch enable signal CLE is at the low level, the memory interface circuit 330 may receive the injection code IJC1 to IJCn. For example, when the write enable signal nWE toggles from the low level to the high level, the injection code IJC1 to IJCn may be received.

For example, the memory interface circuit 330 may receive the data strobe signal DQS which starts to toggle after the address code ADDR is received and a preparation time tADL1/tADL2 passes. The memory interface circuit 330 may receive the data code D0 to Dn based on toggle timings of the data strobe signal DQS.

For example, because the first data signal DQ1 includes the injection code IJC1 to IJCn, the preparation time tADL1 of the first data signal DQ1 may be shorter than the preparation time tADL2 of the second data signal DQ2. For example, the preparation time tADL1 in the injection mode may be shorter than the preparation time tADL2 in the normal mode. For example, as the address code ADDR, the injection code IJC1 to IJCn, and the data code D0 to Dn of the first data signal are sequentially received, the preparation time tADL1 may be shorter than the preparation time tADL2. For example, in the normal mode, as the injection code IJC1 to IJCn is received during a time corresponding to the preparation time tADL1, even though the length of the second data signal DQ2 is longer than the length of the first data signal DQ1, a time used to receive the first data signal DQ1 and a time used to receive the second data signal DQ2 may be identical or similar.

For example, the data strobe signal DQS may toggle after the time tCDQSS for setting up the data strobe signal DQS and the time tWPRE for aligning signals to receive the data code D0 to Dn.

For example, the memory interface circuit 330 may receive the data code D0 to Dn of the first data signal DQ1 or the second data signal DQ2, based on toggle timings of the data strobe signal DQS. For example, when the chip enable signal nCE is at the low level, the address latch enable signal ALE is at the low level, and the command latch enable signal CLE is at the high level, the memory interface circuit 330 may receive the data code D0 to Dn. For example, when the data strobe signal DQS toggles from the low level to the high level, the data code D0 to Dn may be received.

FIG. 11 is a diagram for describing a method in which a memory device receives a data signal designating an erase operation, according to some example embodiments of the present disclosure.

Referring to FIGS. 1, 8, and 11, the chip enable signal nCE, the command latch enable signal CLE, the address latch enable signal ALE, the write enable signal nWE, the first data signal DQ1, and the second data signal DQ2 are illustrated. The signals nCE, CLE, ALE, and nWE may have the states or levels described with reference to FIG. 8, and the data signals DQ1 and DQ2 described with reference to FIG. 1 may be transmitted. Regardless of whether the corresponding signal is at the high level or low level in hatched regions of FIG. 10, the memory device 300 may receive the data signals DQ1 and DQ2.

According to some example embodiments, as described above, the memory device 300 may receive the normal mode signal MOD1; in the first mode, the memory device 300 may receive the second data signal DQ2 including the command CMD, the address ADDR, and data. The memory device 300 may receive the plurality of injection mode signals MOD2 to MODn; in the second mode to the n-th mode, the memory device 300 may receive the first data signal DQ1 including the command CMD, the address ADDR, data, and the injection code IJC.

For example, the second data signal DQ2 may include command codes 60h and D0h and the address code ADDR, and the first data signal DQ1 may include the command codes 60h and D0h, the address code ADDR, and the injection code IJC1 to IJCn. For example, referring to the first data signal, the address code ADDR and the injection code IJC1 to IJCn may be sequentially received.

For example, as the chip enable signal nCE toggles to the enable state (e.g., the low level), the memory interface circuit 330 may transmit/receive the signals CLE, ALE, nWE, DQ1, and DQ2 to/from the memory controller 200. For example, while the signals CLE, ALE, nWE, DQ1, and DQ2 are received, the chip enable signal nCE may maintain the low level.

For example, the memory interface circuit 330 may receive the command codes 60h and D0h of the first data signal DQ1 or the second data signal DQ2, based on toggle timings of the write enable signal nWE. For example, the command codes 60h and D0h may designate the erase operation. For example, when the chip enable signal nCE is at the low level, the command latch enable signal CLE is at the high level, and the address latch enable signal ALE is at the low level, the memory interface circuit 330 may receive the command codes 60h and D0h. For example, when the write enable signal nWE toggles from the low level to the high level, the command codes 60h and D0h may be received.

For example, the memory interface circuit 330 may receive the address code ADDR of the first data signal DQ1 or the second data signal DQ2, based on toggle timings of the write enable signal nWE. For example, when the chip enable signal nCE is at the low level, the address latch enable signal ALE is at the high level, and the command latch enable signal CLE is at the low level, the memory interface circuit 330 may receive the address code ADDR. For example, when the write enable signal nWE toggles from the low level to the high level, the address code ADDR may be received.

For example, the memory interface circuit 330 may receive the injection code IJC1 to IJCn of the first data signal DQ1, based on toggle timings of the write enable signal nWE. For example, as described with reference to FIGS. 4 to 7, the injection code IJC1 to IJCn may include the error address, the error stage, and the error type. For example, when the chip enable signal nCE is at the low level, the address latch enable signal ALE is at the high level, and the command latch enable signal CLE is at the low level, the memory interface circuit 330 may receive the injection code IJC1 to IJCn. For example, when the write enable signal nWE toggles from the low level to the high level, the injection code IJC1 to IJCn may be received.

For example, because the first data signal DQ1 includes the injection code IJC1 to IJCn, the length of the first data signal DQ1 may be longer than the length of the second data signal DQ2. For example, the length of the data signal in the injection mode may be longer than the length of the data signal in the normal mode.

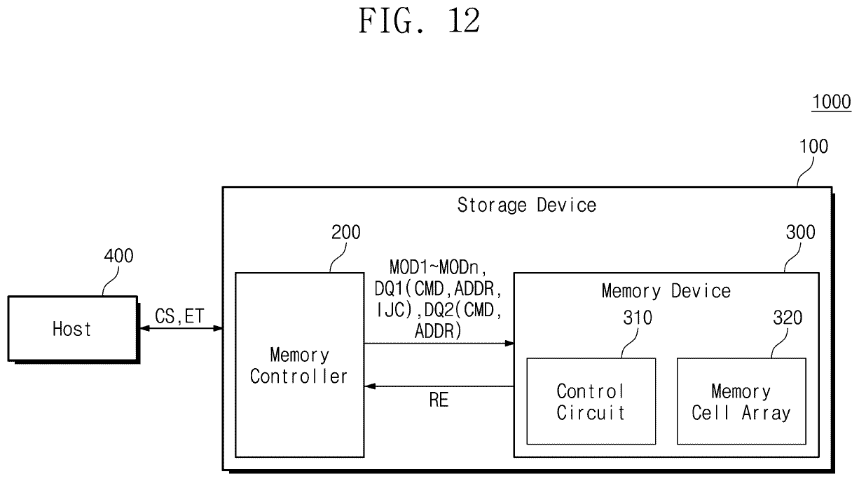

FIG. 12 is a diagram illustrating a storage system, according to some example embodiments of the present disclosure. For brevity of description, additional description associated with the components described above be omitted to avoid redundancy.

Referring to FIG. 12, a storage system 1000 may include the storage device 100 and a host 400. The storage device 100 may be configured to perform the same function as the storage device 100 of FIG. 1.

The host 400 may be configured to overall control operations of the storage device 100. For example, the host 400 may control the storage device 100 to perform the program, read, or erase operation.

According to some example embodiments, the host 400 may be configured to generate a control signal CS. The host 400 may be configured to transmit the control signal CS to the storage device 100. For example, the control signal CS may include a program, read, or erase command. The storage device 100 may be configured to receive the control signal CS, and the memory controller 200 may be configured to generate the second data signal DQ2 based on the control signal CS. For example, the memory controller 200 may be configured to transmit the normal mode signal MOD1 to the memory device 300 based on the control signal CS. The memory device 300 may be configured to receive the second data signal DQ2 based on the normal mode signal MOD1. The memory device 300 may be configured to perform the program, read, or erase operation based on the second data signal DQ2.

According to some example embodiments, the host 400 may be configured to generate an error test signal ET. The host 400 may be configured to transmit the error test signal ET to the storage device 100. For example, the error test signal ET may simulate various errors capable of occurring during the operation of the storage device 100, which is described above. The storage device 100 may be configured to receive the error test signal ET, and the memory controller 200 may be configured to generate the first data signal DQ1 based on the error test signal ET. For example, the memory controller 200 may be configured to transmit one of the plurality of injection mode signals MOD2 to MODn to the memory device 300 based on the error test signal ET. The memory device 300 may be configured to receive the first data signal DQ1 based on one of the plurality of injection mode signals MOD2 to MODn. The memory device 300 may operate based on the first data signal DQ1 such that an error is generated. For example, the first data signal DQ1 may include the command CMD, the address ADDR, and the injection code IJC. The memory device 300 may be configured to perform the operation designated by the command CMD on memory cells designated by the address ADDR such that the error designated by the injection code IJC is generated.

For example, the memory controller 200 may be configured to perform the repair operation on the error, which is described with reference to FIGS. 1 and 2, to determine the result RE of the repair operation, and to output the result RE. For example, the memory controller 200 may be configured to transmit the result RE of the repair operation to the host 400.

As used herein, the term “device” or “unit” refers to any combination of software, firmware, and/or hardware configured to provide the functionality described herein. The software may be implemented, for example, as a software package, a code, and/or an instruction set or an instruction, and the hardware may be implemented, for example, with a hardwired circuit, a programmable circuit, a state machine circuit, and/or an assembly or a single or arbitrary combination of firmware that stores instructions executable by a programmable circuit.

According to the present disclosure, a memory device receives an injection mode signal and changes to one mode among a plurality of injection modes. In the mode, the memory device may receive an injection code in addition to a command and an address. The memory device may operate such that an error designated by the injection code is generated, which makes it possible to accurately simulate an error capable of occurring during an actual operation. Also, it may be possible to selectively generate an error up to the detailed structure of the memory device, such as a word line unit. For example, according to some example embodiments, there may be an improvement in a device longevity, reliability, accuracy, and/or power efficiency of the memory device based on the above methods. Therefore, the improved devices and methods overcome the deficiencies of the conventional devices and methods while reducing resource consumption, and/or improving device life, operating parameters, and resource allocation (e.g., latency).

Any or all of the elements described with reference to the figures may communicate with any or all other elements described with reference to figures. For example, any element may engage in one-way and/or two-way and/or broadcast communication with any or all other elements in the figures, to transfer and/or exchange and/or receive information such as but not limited to data and/or commands, in a manner such as in a serial and/or parallel manner, via a bus such as a wireless and/or a wired bus (not illustrated). The information may be in encoded various formats, such as in an analog format and/or in a digital format.

As described herein, any electronic devices and/or portions thereof according to any of the example embodiments may include, may be included in, and/or may be implemented by one or more instances of processing circuitry such as hardware including logic circuits; a hardware/software combination such as a processor executing software; or any combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a DRAM device, storing a program of instructions, and a processor (e.g., CPU) configured to execute the program of instructions to implement the functionality and/or methods performed by some or all of any devices, systems, modules, units, controllers, circuits, architectures, and/or portions thereof according to any of the example embodiments, and/or any portions thereof.

While the present disclosure has been described with reference to example embodiments thereof, it will be apparent to those of ordinary skill in the art that various changes and modifications may be made thereto without departing from the spirit and scope of the present disclosure as set forth in the following claims.

What is claimed is:

1. An operation method of a memory device which includes memory cells, the method comprising:
receiving an injection mode signal from a memory controller;
changing to one mode among injection modes based on the injection mode signal;
receiving a first data signal including a command, an address, and an injection code from the memory controller, in the one mode; and
performing an operation designated by the command on the memory cells designated by the address such that an error designated by the injection code is generated.

2. The method of claim 1, further comprising:
performing a repair operation on the error to determine a result of the repair operation.

3. The method of claim 1, further comprising:
receiving a normal mode signal from the memory controller; and
changing to a first mode of the injection modes, in which the memory device operates depending on a second data signal, in response to the normal mode signal,
wherein the second data signal includes the command and the address.

4. The method of claim 3, wherein a length of the first data signal is longer than a length of the second data signal.

5. The method of claim 1, wherein
the memory device includes pins, and
the receiving of the first data signal includes:
receiving the command through a first pin among the pins; and
receiving the address through a second pin among the pins.

6. The method of claim 1, wherein
the one mode is a second mode,
the command designates a program operation,
the injection code includes an error address designating one or more memory cells among the memory cells, an error stage designating a first operation included in the program operation, and an error type designating a fail or a hang, and
the performing of the operation designated by the command includes performing the first operation on the one or more memory cells such that the fail or the hang designated by the error type is generated.

7. The method of claim 6, wherein
the first data signal further includes program data targeted for the program operation, and
the receiving of the first data signal includes sequentially receiving the address, the injection code, and the program data.

8. The method of claim 1, wherein
the one mode is a third mode,
the command designates an erase operation,
the injection code includes an error address designating one or more memory cells among the memory cells, an error stage designating a second operation included in the erase operation, and an error type designating a fail or a hang, and
the performing of the operation designated by the command includes performing the second operation on the one or more memory cells such that the fail or the hang designated by the error type is generated.

9. The method of claim 1, wherein
the one mode is a fourth mode,
the command designates a program operation,
the injection code includes an erase count, and
the performing of the operation designated by the command includes programming the memory cells to form an expected threshold voltage distribution which is based on the erase count.

10. The method of claim 9, further comprising:
performing a read operation on the memory cells to determine a lifetime of the memory device.

11. A storage device comprising:
a memory controller configured to transmit a first data signal including a command, an address, and an injection code;
memory cells; and
a control circuit configured to perform an operation designated by the command on the memory cells designated by the address such that an error designated by the injection code is generated.

12. The storage device of claim 11, wherein the memory controller is configured to perform a repair operation on the error to determine a result of the repair operation.

13. The storage device of claim 11, wherein
the memory controller is configured to transmit an injection mode signal or a normal mode signal, and
the control circuit is configured to:
receive the first data signal based on the injection mode signal; and
receive a second data signal including the command and the address based on the normal mode signal.

14. The storage device of claim 13, wherein a length of the first data signal is longer than a length of the second data signal.

15. The storage device of claim 11, wherein
the operation designated by the command is a program operation,
the injection code includes an error address designating one or more memory cells among the memory cells, an error stage designating a first operation included in the program operation, and an error type designating a fail or a hang, and
the control circuit is configured to perform the first operation on the one or more memory cells such that the fail or the hang designated by the error type is generated.

16. The storage device of claim 11, wherein
the operation designated by the command is an erase operation,
wherein the injection code includes an error address designating one or more memory cells among the memory cells, an error stage designating a second operation included in the erase operation, and an error type designating a fail or a hang, and
wherein the control circuit is configured to perform the second operation on the one or more memory cells such that the fail or the hang designated by the error type is generated.

17. The storage device of claim 11, wherein
the operation designated by the command is a program operation,
the injection code includes an erase count, and
the control circuit is configured to program the memory cells to form an expected threshold voltage distribution which is based on the erase count.

18. A storage system comprising:
a host configured to generate a control signal and an error test signal;
a memory controller configured to generate a first data signal including a command, an address, and an injection code, based on the error test signal; and
a memory device configured to perform an operation designated by the command on memory cells designated by the address such that an error designated by the injection code is generated.

19. The storage system of claim 18, wherein the memory controller is configured to perform a repair operation on the error, to determine a result of the repair operation, and to output the result.

20. The storage system of claim 18, wherein
the control signal includes a program command, a read command, or an erase command,
the memory controller is configured to
transmit an injection mode signal to the memory device, based on the error test signal; and
transmit a normal mode signal to the memory device, based on the control signal, and
the memory device is configured to
receive the first data signal based on the injection mode signal; and
receive a second data signal including the command and the address based on the normal mode signal.
